(19) United States
(12) Patent Application Publication
(10) Pub. No.: US 2025/0311543 A1
(43) Pub. Date: Oct. 2, 2025

(54) LIGHT-EMITTING ELEMENT AND DISPLAY DEVICE

(71) Applicant: Sharp Display Technology Corporation, Kameyama City, Mie (JP)

(72) Inventors: Masanobu MIZUSAKI, Kameyama City, Mie (JP); Masakazu SHIBASAKI, Kameyama City, Mie (JP)

(21) Appl. No.: 18/863,408

(22) PCT Filed: May 10, 2022
(86) PCT No.: PCT/JP2022/019801

§ 371 Date: Nov. 6, 2024

(51) Int. Cl. H10K 50/852

(52) U.S. Cl. CPC H10K 50/852

(57) ABSTRACT

A light-emitting element includes a light reflective layer, a first electrode above the light reflective layer, a second electrode above the first electrode, a light-emitting layer between the first electrode and the second electrode, and an optical function layer disposed between the light reflective layer and the first electrode and having a light reflectivity lower than that of the light reflective layer and higher than that of the first electrode.

### TECHNICAL FIELD

The disclosure relates to a light-emitting element and a display device.

### BACKGROUND ART

PTL 1 discloses an organic electroluminescence (EL) element that uses a microcavity system.

### CITATION LIST

### Patent Literature

PTL 1: JP 2013-157226 A

### SUMMARY

### Technical Problem

A light-emitting element that uses a microcavity system has a problem of having a low viewing angle characteristic.

### Solution to Problem

A light-emitting element according to an aspect of the disclosure includes a light reflective layer, a first electrode disposed above the light reflective layer, a second electrode disposed above the first electrode, a light-emitting layer disposed between the first electrode and the second electrode, and an optical function layer disposed between the light reflective layer and the first electrode and having a light reflectivity lower than that of the light reflective layer and higher than that of the first electrode.

### Advantageous Effects of Disclosure

According to an aspect of the disclosure, a viewing angle characteristic of a light-emitting element can be improved.

### BRIEF DESCRIPTION OF DRAWINGS

FIG. 1 is a cross-sectional view illustrating a schematic configuration example of a light-emitting element according to an embodiment of the disclosure.

FIG. 2 is a cross-sectional view illustrating a schematic configuration example of the light-emitting element according to the embodiment of the disclosure.

FIG. 3A is a cross-sectional view illustrating a schematic configuration example of a light-emitting element according to a comparative example.

FIG. 3B shows a wavelength-intensity characteristic of light emitted parallel to a normal line of a second electrode and a wavelength-intensity characteristic of light emitted in a direction forming an acute angle with respect to the normal line of the second electrode, the light being emitted from the light-emitting element of the comparative example illustrated in FIG. 3A to the outside.

FIG. 4 shows a wavelength-intensity characteristic of light emitted from the light-emitting element illustrated in FIG. 2 to the outside in a direction parallel to a normal line of the second electrode.

FIG. 5 shows a wavelength-intensity characteristic of light emitted from the light-emitting element illustrated in FIG. 2 to the outside in a direction forming an acute angle with respect to the normal line of the second electrode.

FIG. 6 is a cross-sectional view illustrating a schematic configuration example of the light-emitting element according to an embodiment of the disclosure.

FIG. 7 is a cross-sectional view illustrating a schematic configuration example of the light-emitting element according to an embodiment of the disclosure.

FIG. 8 is a schematic view illustrating a schematic configuration example of a light reflector illustrated in FIG. 7.

FIG. 9 shows angle-intensity characteristics of light subjected to optical interference by each cavity according to an example of the disclosure, and an angle-intensity characteristic of light obtained by summation of the light.

FIG. 10 shows an angle-intensity characteristic of the light-emitting element according to the example of the disclosure and an angle-intensity characteristic of the light-emitting element of the comparative example.

FIG. 11 shows the angle-intensity characteristic of light subjected to optical interference by each cavity according to an example of the disclosure, and the angle-intensity characteristic of light obtained by summation of the light.

FIG. 12 is a cross-sectional view illustrating a schematic configuration example of the light-emitting element according to an embodiment of the disclosure.

FIG. 13 is a cross-sectional view illustrating the schematic configuration example of the light-emitting element according to an embodiment of the disclosure.

FIG. 14 shows the angle-intensity characteristic of light subjected to optical interference by each cavity according to an example of the disclosure, and the angle-intensity characteristic of light obtained by summation of the light.

FIG. 15 is a plan view illustrating a schematic configuration example of a display device according to an embodiment of the disclosure.

### DESCRIPTION OF EMBODIMENTS

### First Embodiment

### Cross-Sectional Configuration of Light-emitting Element

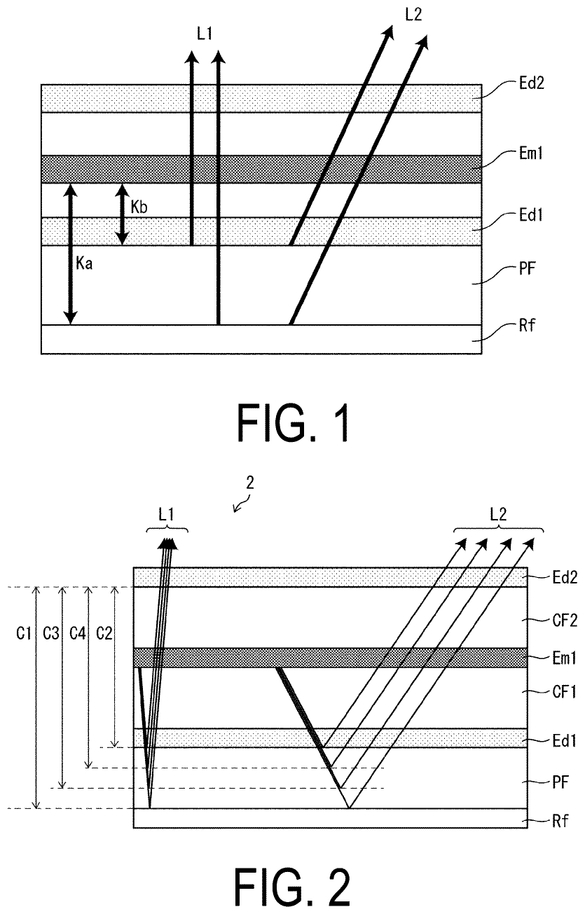

FIG. 1 is a cross-sectional view illustrating a configuration example of a light-emitting element 2 according to the present embodiment. As illustrated in FIG. 1, the light-emitting element 2 includes a light reflective layer Rf, a first electrode Ed1 disposed above the light reflective layer Rf, a second electrode Ed2 disposed above the first electrode Ed1, a light-emitting layer Em1 disposed between the first electrode Ed1 and the second electrode Ed2, and an optical function layer PF disposed between the light reflective layer Rf and the first electrode Ed1 and having a light reflectivity lower than that of the light reflective layer Rf and higher than that of the first electrode Ed1.

In the light-emitting element 2, light reflection occurs at least at an upper face of the optical function layer PF and an upper face of the light reflective layer Rf, and thus a plurality of optical path lengths including an optical path length Ka corresponding to a distance between upper faces of the light-emitting layer Em1 and the light reflective layer Rf and an optical path length Kb corresponding to a distance between the upper faces of the light-emitting layer Em1 and the optical function layer PF are formed for light L1 in a front direction. Therefore, a resonance condition with respect to an optical path length of light L2 in an oblique direction approaches a resonance condition with respect to any of the plurality of optical path lengths of light in the front direction, enhancing a viewing angle characteristic (reducing a color drift between a case of viewing from the front direction and a case of viewing from the oblique direction).

FIG. 2 is a cross-sectional view illustrating an example of the light-emitting element 2 according to the present embodiment. The light-emitting element 2 includes the light reflective layer Rf, the optical function layer PF, the first electrode Ed1, a charge function layer CF1, the light-emitting layer Em1, a charge function layer CF2, and the second electrode Ed2, in this order.

The light reflective layer Rf includes a light reflective substance. The light reflective layer Rf may contain a reflective metal such as silver (Ag), aluminum (Al), and magnesium (Mg), or a reflective inorganic oxide such as titanium oxide (TiO), for example. The light reflective layer Rf preferably has conductivity.

The first electrode Ed1 is a transparent electrode. The transparent electrode may contain a transparent substance having conductivity such as indium tin oxide (InSnO), indium gallium zinc oxide (InGaZnO), and indium zinc oxide (InZnO), for example. The second electrode Ed2 is a semi-transparent electrode. The semi-transparent electrode may be formed of a thin metal film containing silver (Ag) and magnesium (Mg), for example. One of the first electrode Ed1 and the second electrode Ed2 serves as an anode electrode (anode), and the other serves as a cathode electrode (cathode).

The light-emitting layer Em1 may be an organic light-emitting layer containing an organic material that emits fluorescence or phosphorescence, or may be a quantum-dot light-emitting layer containing quantum dots that emit fluorescence or phosphorescence.

### Comparison with Comparative Example

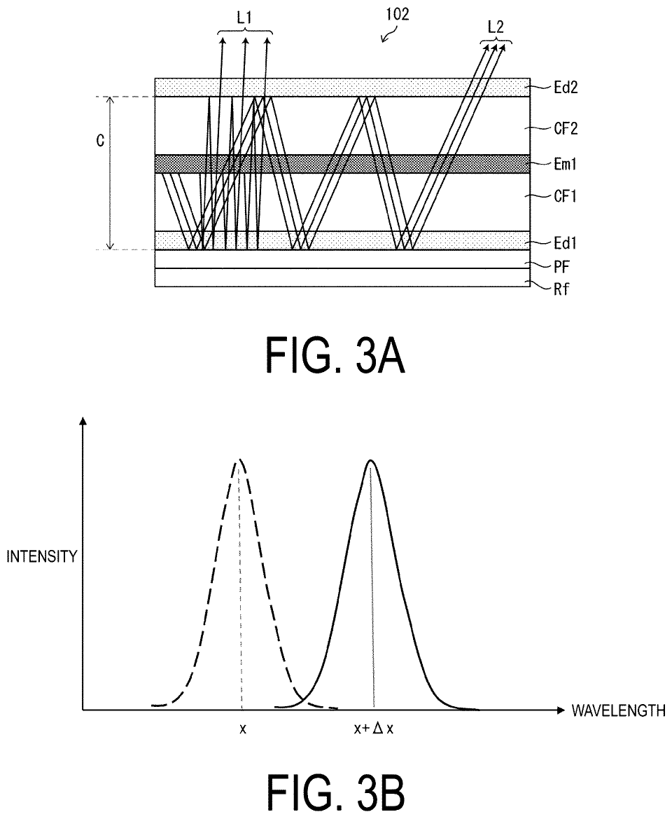

FIG. 3A is a cross-sectional view illustrating a schematic configuration example of a light-emitting element 102 according to a comparative example. The light-emitting element 102 of the comparative example includes a light reflective layer 30, a first electrode 31 disposed directly on the light reflective layer 30, a second electrode 35 disposed above the first electrode 31, and a light-emitting layer 33 disposed between the first electrode 31 and the second electrode 35.

In the light-emitting element 102 of the comparative example, light emitted from the light-emitting layer 33 may be reflected at an upper face position of the light reflective layer 30 and a lower face position of the second electrode 35 and may reciprocate between the upper face position and the lower face position. In other words, the light-emitting element 102 of the comparative example includes a cavity C formed between the upper face position of the light reflective layer 30 and the lower face position of the second electrode 35. In the cavity C, an optical path length of the light L2 emitted in a direction forming an acute angle with respect to a normal line of the second electrode 35 is longer than an optical path length of the light L1 emitted parallel to the normal line of the second electrode 35.

FIG. 3B shows a distribution characteristic of an intensity of the light L1 emitted to the outside from the light-emitting element 102 of the comparative example illustrated in FIG. 3A with respect to wavelength (hereinafter referred to as “wavelength-intensity characteristic”) and a wavelength-intensity characteristic of the light L2. Note that, in order to show the influence of the cavity C, FIG. 3B shows a wavelength-intensity characteristic that is normalized, making a luminance of the light L1 equal to that of the light L2. Specifically, the graph shows a wavelength-intensity characteristic in a case in which the intensity of light emitted by the light-emitting layer 33 is constant, regardless of wavelength.

As shown in FIG. 3B, the wavelength-intensity characteristic of the light L1 is shifted to a long-wavelength side with respect to the wavelength-intensity characteristic of the light L2. One local maximum value is observed in the wavelength-intensity characteristic of the light L1, and a wavelength corresponding to the local maximum value (so-called “peak wavelength”) is represented by x. Another local maximum value is observed in the wavelength-intensity characteristic of the light L2, and a peak wavelength corresponding to the local maximum value is represented by x+Δx. The Δx is greater than 0.

In reality, the intensity of the light emitted by the light-emitting layer 33 typically varies in accordance with wavelength. Therefore, the luminances of the light L1 and the light L2 in the light-emitting element 102 of the comparative example differ from each other, and a difference in the luminance increases as a wavelength shift amount Δx increases, that is, as an angle formed by an emission direction of the light L2 with respect to the normal line of the second electrode Ed2 increases. As a result, there is a problem in that the viewing angle characteristic of the light-emitting element 102 of the comparative example is narrow.

On the other hand, in the light-emitting element 2 of FIG. 2, light reflection occurs at a plurality of positions among an upper face position of the light reflective layer Rf, an upper face position of the optical function layer PF, and an intermediate position in the optical function layer PF. With reference to FIG. 2, a case in which light reflection occurs at the upper face position of the light reflective layer Rf, the upper face position of the optical function layer PF, and two intermediate positions in the optical function layer PF will be described below. Specifically, a case in which the light-emitting element 2 includes (1) a cavity C1 formed between the upper face position of the light reflective layer Rf and a lower face position of the second electrode Ed2, (2) a cavity C2 formed between the upper face position of the optical function layer PF and the lower face position of the second electrode Ed2, and (3) cavities C3, C4 formed between intermediate positions in the optical function layer PF and the lower face position of the second electrode Ed2 will be described below. Regarding respective optical path lengths of the cavities C1 to C4, the optical path length for the light L2 having an acute angle is longer than the optical path length for the light L1 having a parallel angle.

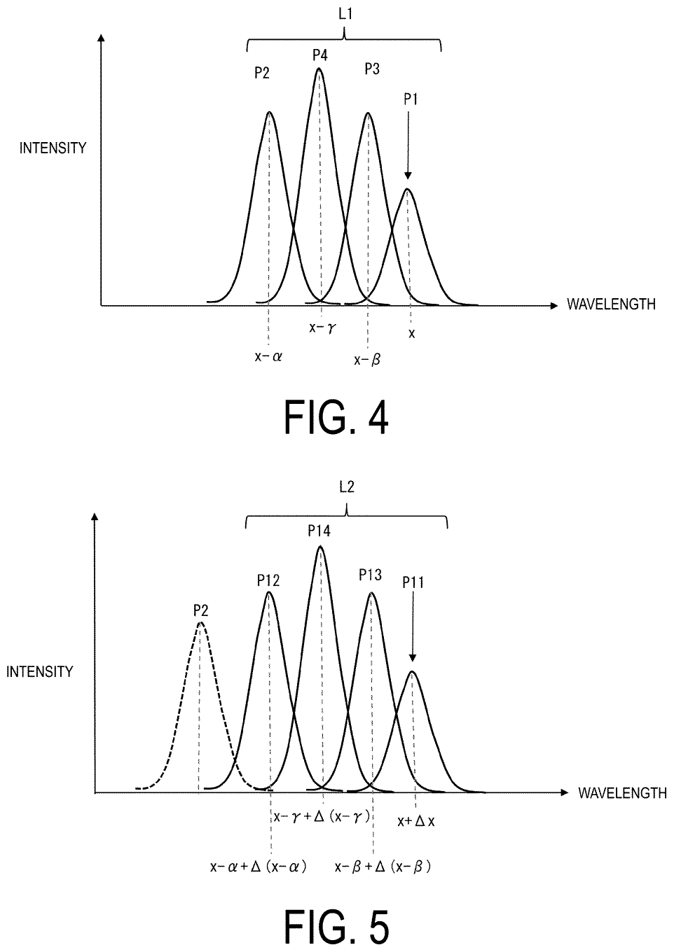

FIG. 4 shows a wavelength-intensity characteristic of the light L1 emitted from the light-emitting element 2 illustrated in FIG. 2 to the outside in a direction parallel to the normal line of the second electrode Ed2. FIG. 5 shows a wavelength-intensity characteristic of the light L2 emitted from the light-emitting element 2 illustrated in FIG. 2 to the outside in a direction forming an acute angle with respect to the normal line of the second electrode Ed2. Note that FIG. 4 and FIG. 5 also show normalized wavelength-intensity characteristics. As shown in FIG. 4, the wavelength-intensity characteristic of the light L1 is a combination of a wavelength-intensity characteristic P1 by the cavity C1, a wavelength-intensity characteristic P2 by the cavity C2, a wavelength-intensity characteristic P3 by the cavity C3, and a wavelength-intensity characteristic P4 by the cavity C4. As shown in FIG. 5, the wavelength-intensity characteristic of the light L2 is a combination of a wavelength-intensity characteristic P11 by the cavity C1, a wavelength-intensity characteristic P12 by the cavity C2, a wavelength-intensity characteristic P13 by the cavity C3, and a wavelength-intensity characteristic P14 by the cavity C4.

Therefore, a plurality of local maximum values are observed in the wavelength-intensity characteristics of the light L1 and the light L2, respectively. x denotes a peak wavelength corresponding to the local maximum value of the wavelength-intensity characteristic P1, x−α denotes a peak wavelength corresponding to the local maximum value of the wavelength-intensity characteristic P2, x−β denotes a peak wavelength corresponding to the local maximum value of the wavelength-intensity characteristic P3, and x−γ denotes a peak wavelength corresponding to the local maximum value of the wavelength-intensity characteristic P2. Further, x>α>γ>β>0. x+Δx denotes a peak wavelength corresponding to the local maximum value of the wavelength-intensity characteristic P11, x−α+Δ(x−α) denotes a peak wavelength corresponding to the local maximum value of the wavelength-intensity characteristic P12, x−β+Δ(x−β) denotes a peak wavelength corresponding to the local maximum value of the wavelength-intensity characteristic P11, and x−γ+Δ(x−γ) denotes a peak wavelength corresponding to the local maximum value of the wavelength-intensity characteristic P12. Further, Δx>0, Δ(x−α)>0, Δ(x−β)>0, and Δ(x−γ)>0. When Δ(x−α)=α, the peak wavelengths of the wavelength-intensity characteristic P1 and the wavelength-intensity characteristic P12 coincide with each other. Furthermore, when Δ(x−β)=β, the peak wavelengths of the wavelength-intensity characteristic P1 and the wavelength-intensity characteristic P13 coincide with each other, and when Δ(x−γ)=γ, the peak wavelengths of the wavelength-intensity characteristic P1 and the wavelength-intensity characteristic P14 coincide with each other.

Accordingly, the viewing angle characteristic of the light-emitting element 2 according to the present embodiment is wide as compared with that of the light-emitting element 102 of the comparative example. Note that, similarly, in a case in which the light-emitting element 2 according to the present embodiment includes two or three cavities or includes five or more cavities, the viewing angle characteristic of the light-emitting element 2 according to the present embodiment is wide as compared with that of the light-emitting element 102 of the comparative example.

Preferably, the peak wavelengths corresponding to each of the plurality of local maximum values observed in the wavelength-intensity characteristic of the light L2 are included in a wavelength range of one primary color. The wavelength range of a primary color is, for example, a blue wavelength range of 440 nm to 490 nm, a green wavelength range of 500 nm to 570 nm, or a red wavelength range of 620 nm to 790 nm. Further, a total thickness of the optical function layer PF is preferably 10 nm to 300 nm.

### Second Embodiment

Another embodiment of the disclosure will be described below. Note that members having the same functions as those of the members described in the above-described embodiment will be denoted by the same reference numerals and signs, and the description thereof will not be repeated for the sake of convenience of description.

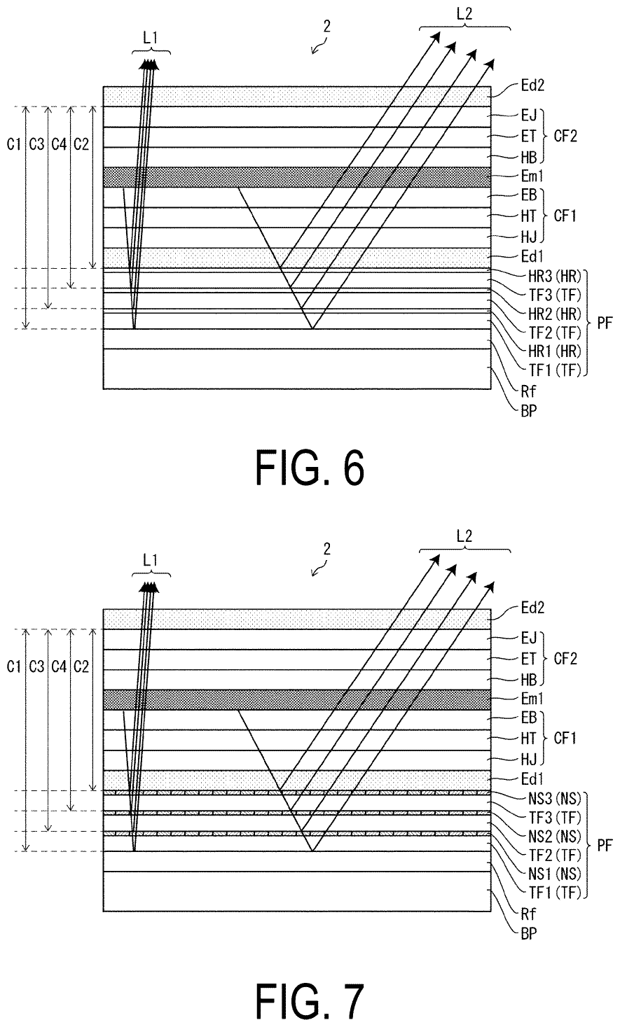

FIG. 6 is a cross-sectional view illustrating a schematic configuration example of the light-emitting element 2 according to the present embodiment. As illustrated in FIG. 6, the light-emitting element 2 according to the present embodiment is positioned on a backplane BP with the first electrode Ed1 being positioned on the backplane BP side and the second electrode Ed2 being positioned on a display surface side. The backplane BP may be provided with a circuit element and a wiring line for driving and controlling the light-emitting element 2.

The light-emitting element 2 according to the present embodiment is the same as the light-emitting element 2 according to the first embodiment described above except that the optical function layer PF includes one or more pairs of a transparent film TF made of a transparent substance and a semi-reflective film HR positioned on the corresponding transparent film TF.

The configuration example illustrated in FIG. 6 is an example in which the optical function layer PF according to the present embodiment includes three pairs of the transparent film TF and the semi-reflective film HR. For ease of description, the transparent film TF positioned on the light reflective layer Rf is referred to as a “first transparent film TF1”, the light semi-reflective film HR positioned on the first transparent film TF1 is referred to as a “first semi-reflective film HR1”, the transparent film TF positioned on the first semi-reflective film HR1 is referred to as a “second transparent film TF2”, the light semi-reflective film HR positioned on the second transparent film TF2 is referred to as a “second semi-reflective film HR2”, the transparent film TF positioned on the second semi-reflective film HR2 is referred to as a “third transparent film TF3”, and the light semi-reflective film HR positioned on the third transparent film TF3 is referred to as a “third semi-reflective film HR3”. In this example, light reflection occurs at the upper face position of the light reflective layer Rf, the upper face position of the optical function layer PF, and intermediate positions in the optical function layer PF. The upper face position of the optical function layer PF includes an upper face position of the third semi-reflective film HR3. Further, the intermediate positions in the optical function layer PF include an upper face position of the first semi-reflective film HR1 and an upper face position of the second semi-reflective film HR2.

The semi-reflective film HR is thinly formed and thus part of the light emitted from the light-emitting layer Em1 reaches the light reflective layer Rf through the optical function layer PF. Therefore, the transparent film TF may be formed thicker than the corresponding semi-reflective film HR. For example, the first transparent film TF1 is thicker than the first semi-reflective film HR1. A thickness of the semi-reflective film HR may be, for example, from 1 nm to 10 nm. In a case in which the optical function layer PF includes a plurality of pairs of the transparent film TF and the semi-reflective film HR, thicknesses of the semi-reflective films HR may be the same or may be different from each other. Similarly, thicknesses of the transparent films TF may be the same or may be different from each other.

The semi-reflective film HR contains a light reflective substance. The semi-reflective film HR may contain a reflective metal such as Ag, Al, or Mg, or a reflective inorganic oxide such as TiO, for example. The semi-reflective film HR preferably has conductivity.

The transparent substance constituting the transparent film TF may contain an inorganic substance or may contain an organic substance. Examples of the transparent inorganic substance include InSnO, InGaZnO, InZnO, silicon nitride (SiN), silicon oxide (SiO), and silicon oxynitride (SiNO). Examples of the transparent organic substance include an acrylic resin, a methacrylic resin, an epoxy resin, a polyimide resin, and a polyamide resin. The transparent substance constituting the transparent film TF preferably has conductivity. Examples of a transparent conductive inorganic substance include InTiO, InGaZnO, and InZnO. Examples of a transparent conductive organic substance include polyphenylene, poly(p-phenylenevinylene), polythiophene, polyfluorene, and polycarbazole.

Each of the charge function layer CF1 and the charge function layer CF2 may include, as appropriate, one or more of a hole injection layer HJ, a hole transport layer HT, an electron blocking layer EB having hole transport properties, an electron injection layer EJ, an electron transport layer ET, a hole blocking layer HB having electron transport properties, and the like.

### Third Embodiment

Another embodiment of the disclosure will be described below. Note that members having the same functions as those of the members described in the above-described embodiments will be denoted by the same reference numerals and signs, and the description thereof will not be repeated for the sake of convenience of description.

FIG. 7 is a cross-sectional view illustrating a schematic configuration example of the light-emitting element 2 according to the present embodiment. As illustrated in FIG. 7, the light-emitting element 2 according to the present embodiment is the same as the light-emitting elements 2 according to the above-described first and second embodiments except that the optical function layer PF includes one set or a plurality of sets of the transparent film TF and a plurality of light reflectors NS disposed above the corresponding transparent film TF. Each of the light reflectors NS is a particle containing a light reflective substance. The configuration example illustrated in FIG. 7 is an example in which the optical function layer PF according to the present embodiment includes a group of three pairs of the transparent film TF and the light reflector NS. For ease of description, the transparent film TF positioned on the light reflective layer Rf is referred to as the “first transparent film TF1”, the light reflector NS positioned on the first transparent film TF1 is referred to as a “first light reflector NS1”, the light semi-reflective film HR positioned on the first light reflector NS1 is referred to as the “first semi-reflective film HR1”, the transparent film TF positioned on the first semi-reflective film HR1 is referred to as the “second transparent film TF2”, the light reflector NS positioned on the second transparent film TF2 is referred to as a “second light reflector NS2”, the transparent film TF positioned on the second light reflector NS2 is referred to as the “third transparent film TF3”, and the light reflector NS positioned on the third transparent film TF3 is referred to as a “third light reflector NS3”. In this example, light reflection occurs at the upper face position of the light reflective layer Rf, the upper face position of the optical function layer PF, and intermediate positions in the optical function layer PF. The upper face position of the optical function layer PF includes an upper face position of the third light reflector NS3. Further, the intermediate positions in the optical function layer PF include an upper face position of the first light reflector NS1 and an upper face position of the second light reflector NS2.

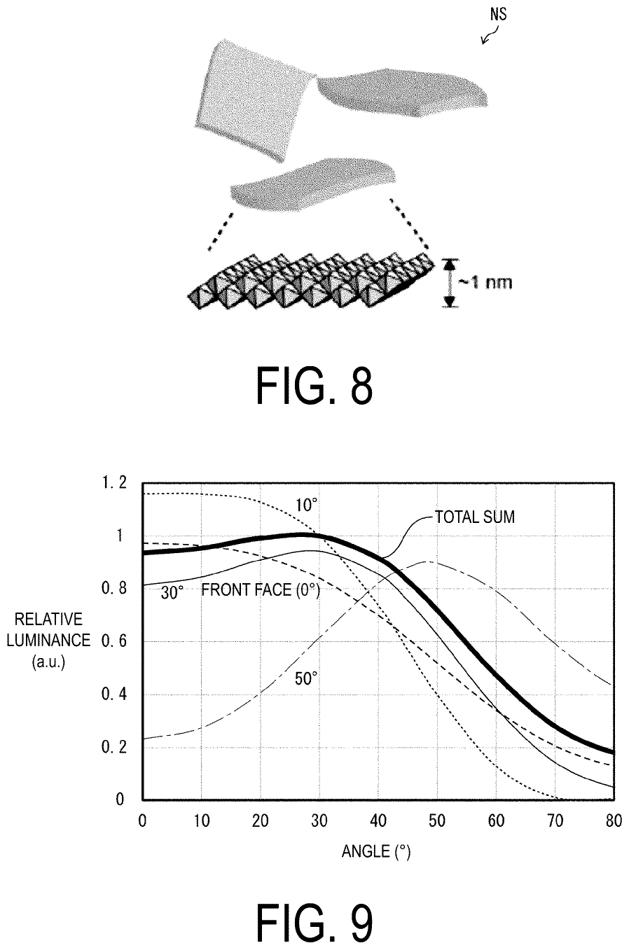

FIG. 8 is a schematic view illustrating a schematic configuration example of the light reflector NS illustrated in FIG. 7. Each of the light reflectors NS may be a nanoparticle having light reflectivity or may be a sheet body having light reflectivity. As illustrated in FIG. 8, the light reflector NS may be a so-called “nanosheet particle”. The nanosheet particle is, for example, approximately 1 nm in thickness and several 10 nm to several 100 nm in diameter.

### EXAMPLE 1

An example of the disclosure will be described below.

First, as the light reflective layer Rf, a 50-nm thick Ag layer was formed on the backplane BP by vapor deposition. Next, as the first transparent film TF1, a 60-nm thick InZnO film was formed on the light reflective layer Rf by a sputtering method. Next, an alcohol solution containing a 1-nm thick sheet body of titanium oxide was prepared, and the alcohol solution was applied onto the first transparent film TF1 and solvent-dried. Thus, as the first light reflector NS1, the sheet body of titanium oxide was arranged on the first transparent film TF1.

Subsequently, as the second transparent film TF2, a 15-nm thick InZnO film was formed on the first light reflector NS1 by a sputtering method. Next, as the second light reflector NS2, a sheet body of titanium oxide was arranged in the same manner as the first light reflector NS1. This process was performed again to form the third transparent film TF3 and arrange the third light reflector NS3.

Subsequently, as the first electrode Ed1, a 20-nm thick InSnO film was formed on the third light reflector NS3 by a sputtering method. Next, as the charge function layer CF1, the hole injection layer HJ, the hole transport layer HT, and the electron blocking layer EB having hole transport properties were formed, in this order. Next, as the light-emitting layer Em1, an organic light-emitting layer that emits blue fluorescence was formed. Next, as the charge function layer CF2, the electron injection layer EJ, the electron transport layer ET, and the hole blocking layer HB having electron transport properties were formed, in this order. Next, as the second electrode Ed2, a thin film of an alloy containing magnesium (Mg) and silver (Ag) was formed by a sputtering method. A thickness of the thin MgAg alloy film was 10 nm.

In this example, the first electrode Ed1 was an anode electrode and the second electrode Ed2 was a cathode electrode. Further, the film formation conditions for the InZnO film in this example were, for the first transparent film TF1, the second transparent film TF2, and the third transparent film TF3, an oxygen doping amount of 6.3%, a film formation temperature of 250 degrees Celsius, and a sputtering voltage of 330 V.

A front luminance ratio of the light-emitting element 2 in a 50° direction was approximately 65%. Accordingly, the viewing angle characteristic was wide. Further, an external quantum efficiency (EQE) was 13.8%, and a chromaticity was (0.137, 0.048) in the CIE 1976 color space. A lifespan until a front luminance of the light-emitting element 2 reached 95% of the initial front luminance under the conditions of 25 degrees Celsius and 50 mA/cm² was 240 hours. Here, the “front luminance ratio in a 50° direction” is the ratio of the 50° luminance to the front luminance, the “front luminance” is the luminance when the light-emitting element 2 is viewed from a direction parallel to the normal line of the second electrode Ed2, and the “50° luminance” is the luminance when the light-emitting element 2 is viewed from a direction forming an acute angle of 50° with respect to the normal line of the second electrode Ed2.

### EXAMPLE 2

An example of the disclosure will be described below.

The light-emitting element 2 according to this example was designed with maximum luminance angles of the light emitted by the light-emitting layer Em1 by the optical interference effect of the cavities C1, C2, C3, C4 being 0°, 50°, 10°, and 30°, respectively. A light-emission peak wavelength of the light-emitting layer Em1 was 456 nm, and a half width of the light emission spectrum was 26 nm. A refractive index of the optical function layer PF was 1.74, and the total thickness of the optical function layer PF was 93 nm. Further, the light-emitting element 102 of the comparative example was designed with the maximum luminance angle of the light emitted by the light-emitting layer Em1 by the optical interference effect of the cavity C being 0°. Here, the “maximum luminance angle” is an angle with respect to the normal line of the second electrode Ed2 at which the intensity of the light emitted by the light-emitting element 2 to the outside is maximum.

FIG. 9 shows angle-intensity characteristics of light subjected to optical interference by each of the cavities C1, C2, C3, C4 according to this example, and an angle-intensity characteristic of light obtained by summation of this light. In FIG. 9, an angle-intensity characteristic by the cavity C1 is indicated by a dash line, an angle-intensity characteristic by the cavity C2 is indicated by an alternate long and short dash line, an angle-intensity characteristic by the cavity C3 is indicated by a dotted line, an angle-intensity characteristic by the cavity C4 is indicated by a thin solid line, and the summed angle-intensity characteristic is indicated by a thick solid line. As shown by the summed angle-intensity characteristic shown in FIG. 9, the front luminance ratio in the 50° direction was approximately 70% in the light-emitting element 2 according to this example. Thus, the light-emitting element 2 according to this example has a wide viewing angle characteristic.

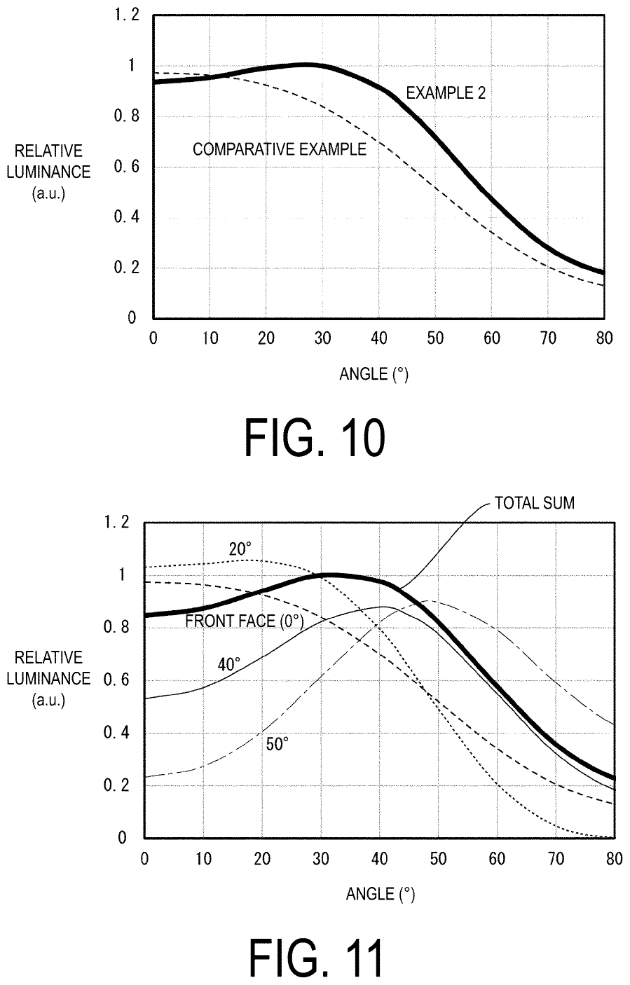

FIG. 10 shows an angle-intensity characteristic of the light-emitting element 2 according to this example and an angle-intensity characteristic of the light-emitting element 102 of the comparative example. The angle-intensity characteristic according to this example shown in FIG. 10 is the same as that of the summed angle-intensity characteristic shown in FIG. 9. As shown in FIG. 10, in the light-emitting element 2 according to this example, the luminance characteristic in the oblique direction is clearly improved as compared with that of the light-emitting element 102 of the comparative example.

### EXAMPLE 3

An example of the disclosure will be described below.

First, the light reflective layer Rf was formed as in Example 1 and then, as the first transparent film TF1, a 40-nm thick acrylic polymer resin film was formed on the light reflective layer Rf by a coating method. Next, as the first light reflector NS1, 15-nm thick nanosheet particles of silver with surfaces modified by an alkyl group were arranged on the first transparent film TF1. Next, the second transparent film TF2 was formed in the same manner as the first transparent film TF1, and the second light reflector NS2 was arranged in the same manner as the first light reflector NS1. This process was performed again to form the third transparent film TF3 and arrange the third light reflector NS3.

Subsequently, the first electrode Ed1 and the charge function layer CF1 were formed as in Example 1. Next, as the light-emitting layer Em1, an organic light-emitting layer that emits green phosphorescence was formed. Next, the charge function layer CF2 and the second electrode Ed2 were formed as in Example 1.

In this example, the first electrode Ed1 was an anode electrode and the second electrode Ed2 was a cathode electrode. The front luminance ratio of the light-emitting element 2 in the 50° direction was approximately 80%. Accordingly, the viewing angle characteristic was wide. Further, the external quantum efficiency (EQE) was 34.5%, and the chromaticity in the CIE 1976 color space was (0.254, 0.710). Under conditions of 25 degrees Celsius and 30 mA/cm², the lifespan of the light-emitting element 2 until the front luminance reached 95% of the initial front luminance was 180 hours.

### EXAMPLE 4

An example of the disclosure will be described below.

The light-emitting element 2 according to this example was designed with maximum luminance angles of the light emitted by the light-emitting layer Em1 by the optical interference effect of the cavities C1, C2, C3, C4 being 0°, 50°, 20°, and 40°, respectively. The light-emission peak wavelength of the light-emitting layer Em1 was 532 nm, and the half width of the light emission spectrum was 56 nm. The refractive index of the optical function layer PF was 1.74, and the total thickness of the optical function layer PF was approximately 185 nm.

FIG. 11 shows angle-intensity characteristics of light subjected to optical interference by each of the cavities C1, C2, C3, C4 according to this example, and an angle-intensity characteristic of light obtained by summation of this light. In FIG. 11, an angle-intensity characteristic by the cavity C1 is indicated by a dash line, an angle-intensity characteristic by the cavity C2 is indicated by an alternate long and short dash line, an angle-intensity characteristic by the cavity C3 is indicated by a dotted line, an angle-intensity characteristic by the cavity C4 is indicated by a thin solid line, and the summed angle-intensity characteristic is indicated by a thick solid line. As shown by the summed angle-intensity characteristic shown in FIG. 11, the front luminance ratio in the 50° direction was approximately 80% in the light-emitting element 2 according to this example. Thus, the light-emitting element 2 according to this example has a wide viewing angle characteristic.

### Fourth Embodiment

Another embodiment of the disclosure will be described below. Note that members having the same functions as those of the members described in the above-described embodiments will be denoted by the same reference numerals and signs, and the description thereof will not be repeated for the sake of convenience of description.

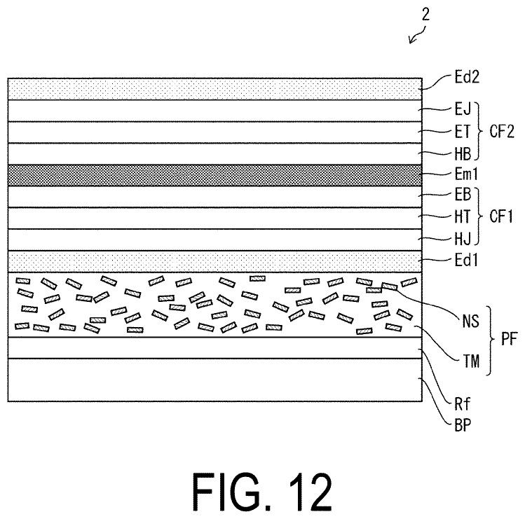

FIG. 12 is a cross-sectional view illustrating a schematic configuration example of the light-emitting element 2 according to the present embodiment. As illustrated in FIG. 12, the light-emitting element 2 according to the present embodiment is the same as the light-emitting elements 2 according to the first to third embodiments described above except that the optical function layer PF includes a transparent medium TM made of a transparent substance and a plurality of the light reflectors NS disposed in the transparent medium TM. The light reflectors NS may be randomly scattered or may be aligned in the transparent medium TM. In the light-emitting element 2 according to the present embodiment, light reflection occurs at the upper face position of the light reflective layer Rf and intermediate positions in the optical function layer PF. The intermediate position in the optical function layer PF includes the upper face position of the light reflector NS.

The transparent substance constituting the transparent medium TM may include an inorganic substance or may include an organic substance, as with the transparent substance constituting the transparent film TF. Further, the transparent substance preferably has conductivity. In a case in which the light reflector NS is a sheet body, the light reflector NS may be oriented with a widest surface of the light reflector NS substantially oriented in the normal direction of the second electrode Ed2 (vertical direction in FIG. 12). The mass ratio of the light reflectors NS to the transparent medium TM may be 10% to 95%.

### EXAMPLE 5

An example of the disclosure will be described below.

First, the light reflective layer Rf was formed as in Example 1 and then, as the optical function layer PF, InSnO and a titanium oxide nanosheet were mixed and deposited on the light reflective layer Rf by a sputtering method. The total thickness of the optical function layer PF was 18 nm, the InSnO constituted the transparent medium TM, and the titanium oxide nanosheets constituted the light reflectors NS. The titanium oxide nanosheets were 1-nm thick and ranged in diameter from several 10 nm to several μm. The titanium oxide nanosheets were oriented with the widest surfaces thereof in the normal direction of the second electrode Ed2 due to shapes thereof. The mass ratio of the titanium oxide nanosheets to the InSnO was InSnO/TiO=50/50. Subsequently, the first electrode Ed1 and the charge function layer CF1 were formed as in Example 1. Next, as the light-emitting layer Em1, an organic light-emitting layer that emits blue fluorescence was formed. Next, the charge function layer CF2 and the second electrode Ed2 were formed as in Example 1.

In this example, the first electrode Ed1 was an anode electrode and the second electrode Ed2 was a cathode electrode. Further, the film formation conditions of InSnO in this example were an oxygen doping amount of 17.3%, a film formation temperature of 250 degrees Celsius, and a sputtering voltage of 250 V.

The front luminance ratio of the light-emitting element 2 in the 50° direction was approximately 62%. Accordingly, the viewing angle characteristic was wide. Further, the external quantum efficiency (EQE) was 12.2%, and the chromaticity in the CIE 1976 color space was (0.136, 0.047). Under conditions of 25 degrees Celsius and 50 mA/cm², the lifespan of the light-emitting element 2 until the front luminance reached 95% of the initial front luminance was 265 hours.

### Fifth Embodiment

Another embodiment of the disclosure will be described below. Note that members having the same functions as those of the members described in the above-described embodiments will be denoted by the same reference numerals and signs, and the description thereof will not be repeated for the sake of convenience of description.

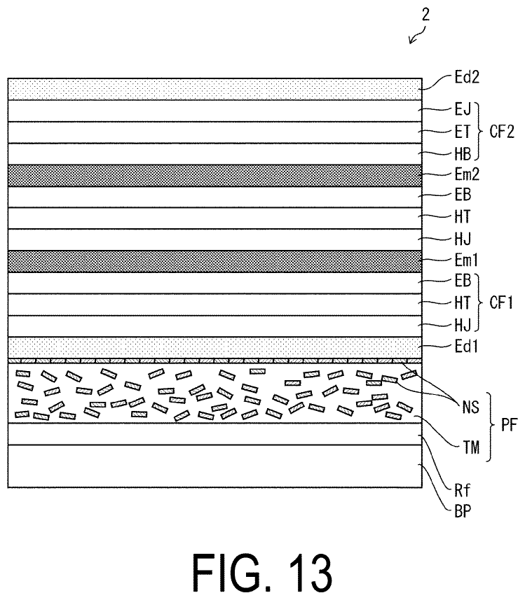

FIG. 13 is a cross-sectional view illustrating a schematic configuration example of the light-emitting element 2 according to the present embodiment. As illustrated in FIG. 13, in the light-emitting element 2 according to the present embodiment, in addition to the configuration of the light-emitting elements 2 according to the first to fourth embodiments described above, another light-emitting layer Em2 that emits light of the same color as the light-emitting layer Em1 is arranged between the first electrode Ed1 and the second electrode Ed2. The light-emitting layer Em2 may be an organic light-emitting layer containing an organic material that emits fluorescence or phosphorescence, or may be a quantum-dot light-emitting layer containing quantum dots that emit fluorescence or phosphorescence.

The light-emitting element 2 may further include a charge function layer CF3 between the two layers of the light-emitting layer Em1 and the light-emitting layer Em2. The charge function layer CF3 may include, as appropriate, any one or more of the hole blocking layer HB, the electron transport layer ET, a charge generating layer CG, the hole transport layer HT, the electron blocking layer EB having hole transport properties, and the like.

### EXAMPLE 6

An example of the disclosure will be described below.

First, the light reflective layer Rf was formed as in Example 1. Next, the optical function layer PF was formed as in Example 1 except that the total thickness of the optical function layer PF was 36 nm. Subsequently, the first electrode Ed1 and the charge function layer CF1 were formed as in Example 1. Next, as the light-emitting layer Em1, an organic light-emitting layer that emits red phosphorescence was formed. Next, as the charge function layer CF2, the hole blocking layer HB having electron transport properties, the electron transport layer ET, the charge generating layer CG, the hole transport layer HT, and the electron blocking layer EB having hole transport properties were formed, in this order. Next, as the light-emitting layer Em2, an organic light-emitting layer that emits red phosphorescence was formed. Next, the charge function layer CF2 and the second electrode Ed2 were formed as in Example 1.

In this example, the first electrode Ed1 was an anode electrode and the second electrode Ed2 was a cathode electrode. The front luminance ratio of the light-emitting element 2 in the 50° direction was approximately 80%. Accordingly, the viewing angle characteristic was wide. Further, the external quantum efficiency (EQE) was 65.7%, and the chromaticity in the CIE 1976 color space was (0.692, 0.307). Under conditions of 25 degrees Celsius and 50 mA/cm², the lifespan of the light-emitting element 2 until the front luminance reached 95% of the initial front luminance was 1740 hours.

### EXAMPLE 7

An example of the disclosure will be described below.

The light-emitting element 2 according to this example was designed with maximum luminance angles of the light emitted from the light-emitting layers Em1, Em2 by the optical-interference effect of the cavities C1, C2, C3, C4 being 0°, 50°, 10°, and 40°, respectively. The light-emission peak wavelength of the light-emitting layers Em1, Em2 was 626 nm, and the half width of the light emission spectrum was 59 nm. The refractive index of the optical function layer PF was 1.74, and the total thickness of the optical function layer PF was approximately 36 nm.

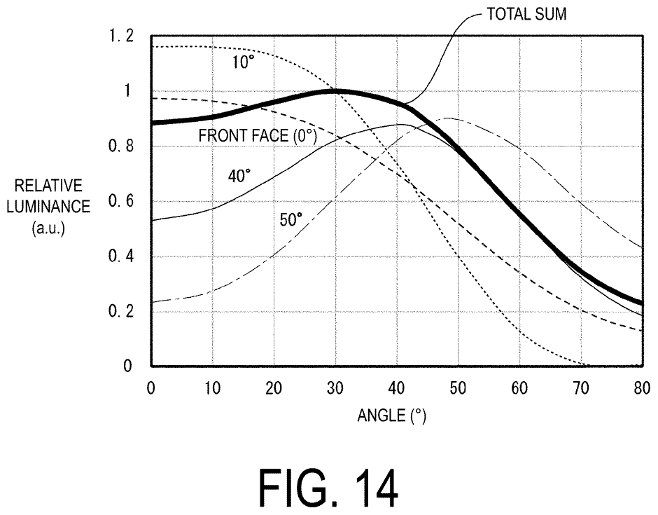

FIG. 14 shows angle-intensity characteristics of light subjected to optical interference by each of the cavities C1, C2, C3, C4 according to this example, and an angle-intensity characteristic of light obtained by summation of this light. In FIG. 14, an angle-intensity characteristic by the cavity C1 is indicated by a dash line, an angle-intensity characteristic by the cavity C2 is indicated by an alternate long and short dash line, an angle-intensity characteristic by the cavity C3 is indicated by a dotted line, an angle-intensity characteristic by the cavity C4 is indicated by a thin solid line, and the summed angle-intensity characteristic is indicated by a thick solid line. As shown by the summed angle-intensity characteristic shown in FIG. 14, the front luminance ratio in the 50° direction was approximately 80% in the light-emitting element 2 according to this example. Thus, the light-emitting element 2 according to this example has a wide viewing angle characteristic.

### Sixth Embodiment

Another embodiment of the disclosure will be described below. Note that members having the same functions as those of the members described in the above-described embodiments will be denoted by the same reference numerals and signs, and the description thereof will not be repeated for the sake of convenience of description.

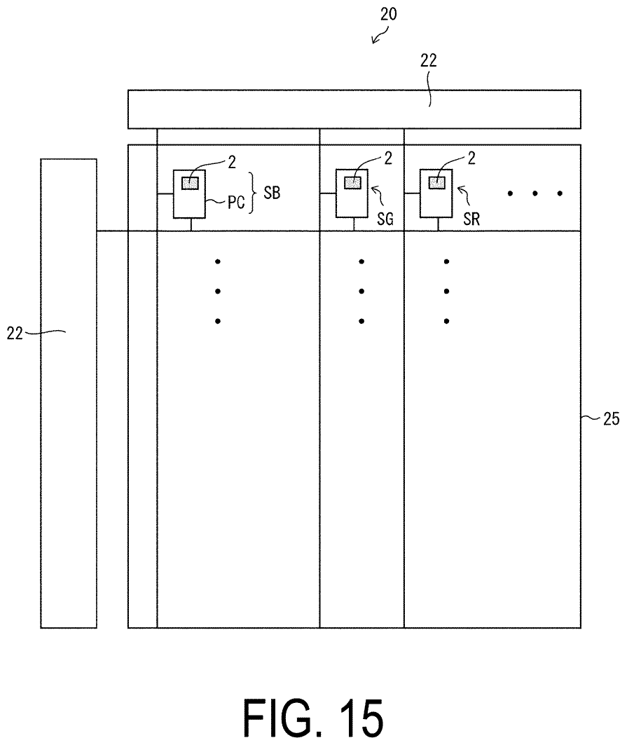

FIG. 15 is a plan view illustrating a schematic configuration example of a display device according to the present embodiment. As illustrated in FIG. 15, a display device 20 includes a display portion 25 including a plurality of subpixels SB, SG, and SR, and a driver 22 for driving the plurality of subpixels SB, SG, and SR. For example, the subpixel SB includes the light-emitting element ED and a pixel circuit PC connected to the light-emitting element ED. The subpixel SB may be a blue subpixel including the light-emitting element 2 that emits blue light. The subpixel SG may be a green subpixel including the light-emitting element 2 that emits green light, and the subpixel SR may be a red subpixel including the light-emitting element 2 that emits red light.

As described above with reference to FIG. 3A and FIG. 3B, the viewing angle characteristic of the light-emitting element 102 of the comparative example is narrow. The viewing angle characteristics of the blue light-emitting element, the green light-emitting element and the red light-emitting element are typically different. Therefore, in a display device including the light-emitting elements 102 of the comparative example as a blue light-emitting element, a green light-emitting element, and a red light-emitting element, there is a problem in that, when a screen displaying white is viewed from an oblique direction, the screen appears colored. Furthermore, there is also a problem in that the luminance of a display screen of the display device 4 is lower when viewed obliquely than when viewed from the front.

On the other hand, as described above, the viewing angle characteristic of the light-emitting element 2 according to the disclosure is wide. Therefore, in a display device including the light-emitting elements 2 according to the disclosure as a blue light-emitting element, a green light-emitting element, and a red light-emitting element, even when the screen displaying white is viewed from an oblique direction, the screen is unlikely to be colored. For example, in a case in which the front luminance ratio in the 50° direction is approximately 60% or greater or approximately 80% or greater for any of the blue light-emitting element, the green light-emitting element, and the red light-emitting element, even if the display screen is viewed from a direction forming an acute angle of 50°, the screen is not significantly colored and the screen is not significantly darkened as compared with when viewed from the front.

The disclosure is not limited to each of the embodiments described above, and various modifications may be made within the scope of the claims. Embodiments obtained by appropriately combining technical approaches disclosed in each of the different embodiments also fall within the technical scope of the disclosure. Furthermore, novel technical features can be formed by combining the technical approaches disclosed in each of the embodiments.

1. A light-emitting element comprising:
a light reflective layer;
a first electrode disposed above the light reflective layer;
a second electrode disposed above the first electrode;
a light-emitting layer disposed between the first electrode and the second electrode; and
an optical function layer disposed between the light reflective layer and the first electrode and having a light reflectivity lower than a light reflectivity of the light reflective layer and higher than a light reflectivity of the first electrode.

2. The light-emitting element according to claim 1,
wherein light reflection occurs at a plurality of positions among an upper face position of the optical function layer, an upper face position of the light reflective layer, and an intermediate position in the optical function layer.

3. The light-emitting element according to claim 2,
wherein a plurality of local maximum values are observed in a wavelength-intensity characteristic of light emitted from the second electrode in a direction forming an acute angle with respect to a normal line of the second electrode, and
wavelengths respectively corresponding to the plurality of local maximum values are each included in a wavelength range of one primary color.

4. The light-emitting element according to claim 1,
wherein a thickness of the optical function layer is 10 nm to 300 nm.

5. The light-emitting element according to claim 1,
wherein the optical function layer includes a first transparent film positioned on the light reflective layer and made of a transparent substance.

6. The light-emitting element according to claim 5,
wherein the optical function layer includes a first semi-reflective film positioned on the first transparent film.

7. The light-emitting element according to claim 6,
wherein the optical function layer includes
a second transparent film positioned on the first semi-reflective film, and
a second semi-reflective film positioned on the second transparent film.

8. The light-emitting element according to claim 6,
wherein the first transparent film is thicker than the first semi-reflective film.

9. The light-emitting element according to claim 6,
wherein a thickness of the first semi-reflective film is 1 nm or greater and less than 10 nm.

10. The light-emitting element according to claim 6,
wherein the first semi-reflective film contains at least one of Ag, Al, Ti, and Mg.

11. The light-emitting element according to claim 5,
wherein the optical function layer includes a plurality of light reflectors disposed above the first transparent film.

12. The light-emitting element according to claim 1,
wherein the optical function layer includes
a transparent medium made of a transparent substance, and
a plurality of light reflectors disposed in the transparent medium.

13. The light-emitting element according to claim 12,
wherein a mass ratio of the plurality of light reflectors to the transparent medium is 10% to 95%.

14. The light-emitting element according to claim 11,
wherein each of the plurality of light reflectors is a nanoparticle having light reflectivity.

15. The light-emitting element according to claim 11,
wherein each of the plurality of light reflectors is a sheet body having light reflectivity.

16. (canceled)

17. (canceled)

18. The light-emitting element according to claim 5,
wherein the transparent substance is an organic substance.

19. The light-emitting element according to claim 18,
wherein the organic substance contains at least one of an acrylic resin, a methacrylic resin, an epoxy resin, a polyimide resin, and a polyamide resin.

20. The light-emitting element according to claim 18,
wherein the organic substance has conductivity.

21. The light-emitting element according to claim 20,
wherein the organic substance contains at least one of polyphenylene, poly(p-phenylenevinylene), polythiophene, polyfluorene, and polycarbazole.

22. The light-emitting element according to claim 1,
wherein another light-emitting layer configured to emit light of the same color as a color of light of the light-emitting layer is disposed between the first electrode and the second electrode.

23. (canceled)
